(19) United States
(12) Patent Application Publication
(10) Pub. No.: US 2026/0130081 A1
(43) Pub. Date: May 7, 2026

(54) DISPLAY PANEL AND DISPLAY APPARATUS

(71) Applicant: Wuhan Tianma Microelectronics Co., Ltd., Wuhan (CN)

(72) Inventor: Lei LI, Wuhan (CN)

(73) Assignee: Wuhan Tianma Microelectronics Co., Ltd., Wuhan (CN)

(21) Appl. No.: 19/440,989

(22) Filed: Jan. 6, 2026

(30) Foreign Application Priority Data
Oct. 27, 2025 (CN) 202511543578.6

(51) Int. Cl. H10K 59/131

(52) U.S. Cl. CPC H10K 59/131

(57) ABSTRACT

Provided are a display panel and a display apparatus. The display panel includes a display area and a non-display area, the non-display area including a bonding area; wherein the display panel comprises a substrate, and metal bumps and organic layers located on one side of the substrate, the organic layers have a hollow located in the bonding area, and the metal bumps are located in the hollow; and wherein at least one of the organic layers has a groove, and the groove is in communication with the hollow and extends in a direction away from the hollow. The groove can be utilized as a bubble release path, preventing an anisotropic conductive adhesive from generating bubble accumulation at the boundary position of the organic layer, thereby being capable of preventing film layer peeling between the anisotropic conductive adhesive and metal and improving product reliability.

### CROSS-REFERENCE TO RELATED APPLICATION

The present application claims priority to Chinese Patent Application No. 202511543578.6, filed on October 27, 2025, the content of which is incorporated herein by reference in its entirety.

### TECHNICAL FIELD

The present application relates to the field of display technologies, and in particular, to a display panel and a display apparatus.

### BACKGROUND

At present, the design of display products is continuously optimized in terms of high refresh rate, narrow bezel, high display effect, and other aspects to meet market demands. OLED (Organic Light-Emitting Diode) products have become a mainstream design in the market due to their advantages such as thinness and lightness, high brightness, low power consumption, fast response speed, high definition, good flexibility, and high luminous efficiency. A driver chip is bonded to metal bumps on a display panel via an anisotropic conductive adhesive, whereby signals are provided to signal lines in a display area through the metal bumps. In some usage scenarios, there is a risk of peeling between the anisotropic conductive adhesive and the metal bumps, which may in turn lead to failure.

### SUMMARY

In a first aspect, an embodiment of the present application provides a display panel including a display area and a non-display area, the non-display area including a bonding area;

where the display panel includes a substrate, and metal bumps and organic layers that are located on one side of the substrate, the organic layers having a hollow located in the bonding area, and the metal bumps being located in the hollow; and

where at least one of the organic layers has a groove, the groove being in communication with the hollow and extending in a direction away from the hollow.

In a second aspect, an embodiment of the present application further provides a display apparatus including a display panel, where the display panel includes a display area and a non-display area, the non-display area including a bonding area;

where the display panel includes a substrate, and metal bumps and organic layers that are located on one side of the substrate, the organic layers having a hollow located in the bonding area, and the metal bumps being located in the hollow; and

where at least one of the organic layers has a groove, the groove being in communication with the hollow and extending in a direction away from the hollow.

### BRIEF DESCRIPTION OF DRAWINGS

To more clearly illustrate the technical solutions in the embodiments of the present application or in the prior art, the accompanying drawings required for describing the embodiments or the prior art will be briefly introduced below. The accompanying drawings in the following description are some embodiments of the present application, and for those of skill in the art, other accompanying drawings can also be obtained based on these accompanying drawings.

FIG. 1 is a partial schematic diagram of a display panel in the related art;

FIG. 2 is a schematic diagram of a display panel according to an embodiment of the present application;

FIG. 3 is a cross-sectional schematic diagram taken at the position of section line A-A’ in FIG. 2;

FIG. 4 is another schematic diagram of a display panel according to an embodiment of the present application;

FIG. 5 is another schematic diagram of a display panel according to an embodiment of the present application;

FIG. 6 is a cross-sectional schematic diagram taken at the position of section line B-B’ in FIG. 5;

FIG. 7 is another schematic diagram of a display panel according to an embodiment of the present application;

FIG. 8 is another schematic diagram of a display panel according to an embodiment of the present application;

FIG. 9 is another schematic diagram of a display panel according to an embodiment of the present application;

FIG. 10 is another partial schematic diagram of a display panel according to an embodiment of the present application;

FIG. 11 is another cross-sectional schematic diagram taken at the position of section line A-A’ in FIG. 2;

FIGS. 12A and 12B are top view schematic diagrams of a first organic layer and a second organic layer in a bonding area in FIG. 11;

FIG. 13 is a schematic diagram of a film layer structure of a display panel according to an embodiment of the present application;

FIG. 14 is another cross-sectional schematic diagram taken at the position of section line A-A’ in FIG. 2;

FIG. 15 is another schematic diagram of a film layer structure of a display panel according to an embodiment of the present application;

FIG. 16 is another cross-sectional schematic diagram taken at the position of section line A-A’ in FIG. 2;

FIGS. 17A, 17B, and 17C are partial top view schematic diagrams of three organic layers in the bonding area in FIG. 16;

FIG. 18 is another cross-sectional schematic diagram taken at the position of section line A-A’ in FIG. 2;

FIG. 19 is another cross-sectional schematic diagram taken at the position of section line A-A’ in FIG. 2; and

FIG. 20 is a schematic diagram of a display apparatus according to an embodiment of the present application.

### DESCRIPTION OF EMBODIMENTS

To make the objects, technical solutions, and advantages of the embodiments of the present application clearer, the technical solutions in the embodiments of the present application will be described clearly and completely below with reference to the accompanying drawings in the embodiments of the present application. The described embodiments are some rather than all of the embodiments of the present application. All other embodiments obtained by those of ordinary skill in the art based on the embodiments of the present application shall fall within the protection scope of the present application.

The terms used in the embodiments of the present application are merely for the purpose of describing specific embodiments, and are not intended to limit the present application. The singular forms “a/an”, “said”, and “the” used in the embodiments of the present application and the appended claims are also intended to include the plural forms thereof, unless the context clearly indicates otherwise.

Without departing from the spirit or scope of the present application, various modifications and changes may be made in the present application, which is obvious to those of ordinary skill in the art. Therefore, the present application intends to cover the modifications and changes of the present application that fall within the scope of the corresponding claims (claimed technical solutions) and their equivalents. It should be noted that the implementations provided by the embodiments of the present application may be combined with each other in the absence of conflict.

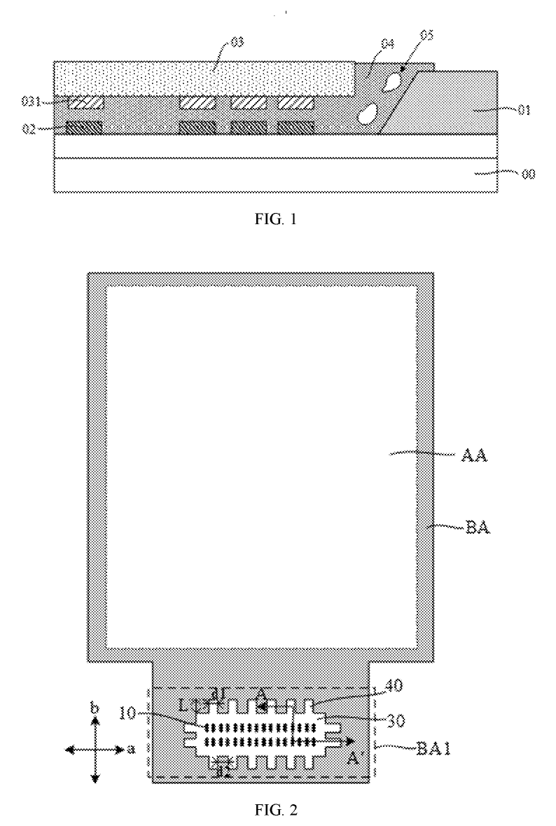

In the related art, a display panel has a risk of failure when used in a high-temperature and high-humidity environment, and the risk of failure is due to peeling between an anisotropic conductive adhesive and metal occurring at the bonding position between a driver chip and the panel. FIG. 1 is a partial schematic diagram of a display panel in the related art. As shown in FIG. 1, the display panel includes a substrate 00, an organic layer 01, and metal bumps 02. A hollow exposing the metal bumps 02 is formed in the organic layer 01, the metal bumps 02 are electrically connected to terminals 031 on a driver chip 03 through an anisotropic conductive adhesive 04, and conductive particles (not shown in FIG. 1) are present between the metal bumps 02 and the overlapping terminals 031. As can be seen from FIG. 1, there is a step difference between the driver chip 03 and the boundary of the organic layer 01. During a bonding process of the driver chip 03 and the panel, the step difference between the anisotropic conductive adhesive 04 and the boundary of the organic layer 01 easily causes the anisotropic conductive adhesive 04 to accumulate at the boundary position of the organic layer 01. The anisotropic conductive adhesive 04 accumulated at the boundary position of the organic layer 01 cannot be released, resulting in bubbles 05. Considering use in a high-temperature and high-humidity environment, sweat from the palm provides an environmental factor that causes corrosion to devices in the display panel. The sweat reaches the vicinity of the driver chip 03 through gaps of conductive cloth, penetrates into the anisotropic conductive adhesive 04 through the bubbles 05 at the boundary position of the organic layer 01, and in turn leads to peeling between the anisotropic conductive adhesive 04 and metal, resulting in bonding failure.

To solve the problem existing in the related art, the embodiments of the present application provide a display panel. A groove is provided in at least one organic layer at the bonding position between the display panel and a driver chip, and the groove is in communication with the hollow exposing the metal bumps, whereby the groove can be utilized as a release path for the anisotropic conductive adhesive during the bonding process, avoiding the accumulation of the anisotropic conductive adhesive at the boundary position of the organic layer and the generation of bubbles. Thus, the risk of peeling between the anisotropic conductive adhesive and metal when the display panel is used in a high-temperature and high-humidity environment is reduced. The above is the main technical concept of the present application, and the present application is illustrated below with specific embodiments.

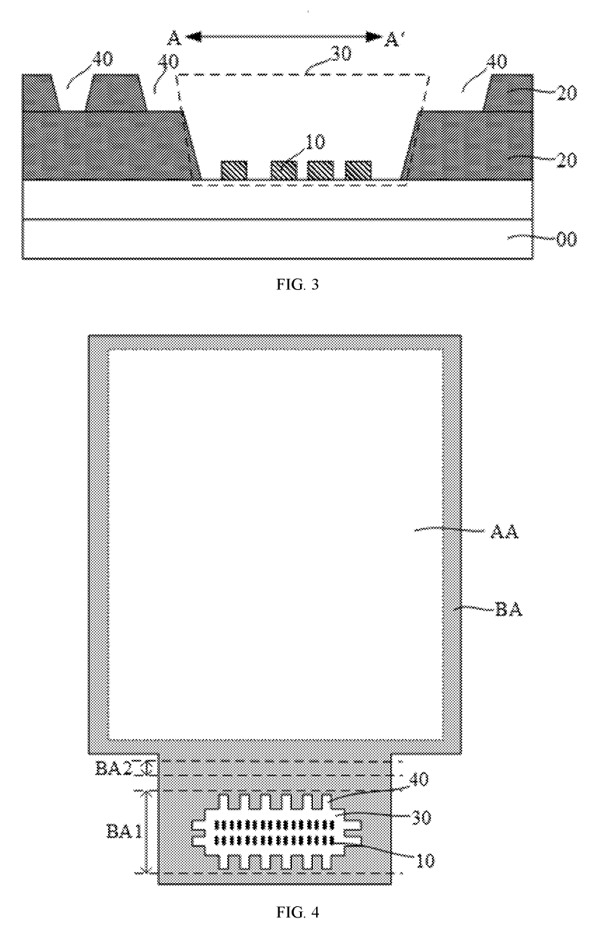

FIG. 2 is a schematic diagram of a display panel according to an embodiment of the present application, and FIG. 3 is a cross-sectional schematic diagram taken at the position of section line A-A’ in FIG. 2. As can be seen in combination with FIGS. 2 and 3, the display panel includes a display area AA and a non-display area BA, and the non-display area BA includes a bonding area BA1. The display panel includes a substrate 00, metal bumps 10 and organic layers 20 located on one side of the substrate 00. The organic layers 20 have a hollow 30 located in the bonding area BA1, and the metal bumps 10 are located in the hollow 30. The metal bumps 10 can be used for bonding connection with a driver chip, and the driver chip can provide signals to the display area AA through the metal bumps 10. Herein, at least one of the organic layers 20 has a groove 40, and the groove 40 is in communication with the hollow 30 and extends in a direction away from the hollow 30. In FIG. 2, a shape of the groove 40 in a top view is schematically shown as approximately a rectangle. In the embodiments of the present application, there is no limitation on the shape of the groove 40, and the shape thereof in the top view may be a regular shape such as a rectangle, a trapezoid, a triangle, etc., or an irregular shape. The groove 40 may be a linear groove in its extending direction, or a groove with a corner.

In the display panel according to the embodiment of the present application, the groove 40 is formed in at least one of the organic layers 20 at the position of the bonding area BA1, and the groove 40 is in communication with the hollow 30 exposing the metal bumps 10 in the organic layer 20. During the bonding process of bonding the driver chip, the communication between the groove 40 and the hollow 30 can increase the flow space of the anisotropic conductive adhesive, the anisotropic conductive adhesive can flow from the hollow 30 toward the groove 40, and the groove 40 is utilized as a bubble release path, preventing the anisotropic conductive adhesive from generating bubble accumulation at the boundary position of the organic layer 20 (i.e., the boundary of the organic layer where the hollow is formed or where the groove is formed). This is equivalent to cutting off the invasion path of moisture and sweat, thereby being capable of preventing film layer peeling between the anisotropic conductive adhesive and metal and improving product reliability.

In some implementations, FIG. 4 is another schematic diagram of a display panel according to an embodiment of the present application. As shown in FIG. 4, the non-display area BA further includes a bending area BA2, and the bending area BA2 is located between the display area AA and the bonding area BA1. After the bending area BA2 is bent, the bonding area BA1 is placed on one side away from a light-emitting surface of the display panel, whereby the frame width of the display panel can be reduced.

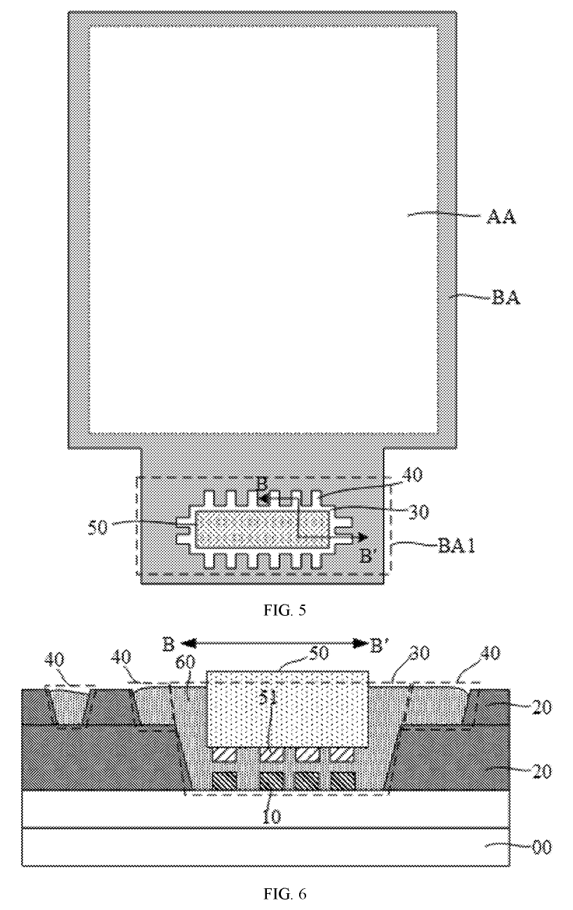

In some implementations, FIG. 5 is another schematic diagram of a display panel according to an embodiment of the present application, and FIG. 6 is a cross-sectional schematic diagram taken at the position of section line B-B’ in FIG. 5. As can be seen in combination with FIGS. 5 and 6, the display panel includes a driver chip 50, and the driver chip 50 includes a plurality of pins 51; and in the hollow 30, the pins 51 and the metal bumps 10 are connected through an anisotropic conductive adhesive 60. Conductive particles (not shown in FIG. 6) are doped in the anisotropic conductive adhesive 60, and during the bonding process, the pins 51 and the metal bumps 10 are electrically connected through the conductive particles by applying pressure. As can be seen from FIG. 6, the anisotropic conductive adhesive 60 fills at least part of the groove 40. During the bonding process of bonding the driver chip 50, the anisotropic conductive adhesive 60 can flow from the hollow 30 toward the groove 40, and the groove 40 is utilized as a bubble release path, preventing the anisotropic conductive adhesive 60 from generating bubble accumulation at the boundary position of the organic layer 20. This is equivalent to cutting off the invasion path of moisture and sweat, thereby being capable of preventing film layer peeling between the anisotropic conductive adhesive 60 and metal (i.e., the metal bumps 10 and the pins 51) and improving product reliability.

In some implementations, as shown in FIG. 2, a length of the groove 40 in its extending direction is L. If the groove 40 extends along a first direction a, the length thereof in the first direction a is L; and if the groove 40 extends along a second direction b, the length thereof in the second direction b is L. Herein, L≥100μm. The inventor analyzed and measured that the size of bubbles generated by the accumulation of the anisotropic conductive adhesive is about 100μm. In the embodiment of the present application, it is set that L≥100μm. On one hand, the groove 40 can be utilized to increase the flow space of the anisotropic conductive adhesive, preventing the anisotropic conductive adhesive from accumulating and generating bubbles; on the other hand, the length of the groove 40 is equivalent to the size of the bubbles, and when bubbles have been generated in the anisotropic conductive adhesive, the bubbles can also move to the position of the groove 40 and then burst, preventing the bubbles from accumulating at the boundary position of the organic layer 20.

In some implementations, L≤150μm. That is, the length of the groove 40 is not set too large. While meeting the requirement of utilizing the groove 40 as a bubble release path to prevent the anisotropic conductive adhesive 60 from generating bubble accumulation at the boundary position of the organic layer 20, the waste of space and materials caused by an excessively large length L of the groove 40 is also avoided.

In some implementations, along a direction perpendicular to an extending direction of the groove 40, a width of the groove 40 is d1, and 50μm≤d1≤100μm. As shown in FIG. 2, the length L of the groove 40 extending along the second direction b is marked, and the width of the groove 40 along the first direction a is d1. In this implementation, the width range of the groove 40 is limited. The width of the groove 40 is not too small to ensure the requirement of bubble release, and the width of the groove 40 is not too large so that a certain number of grooves can be arranged in an arrangement direction of the grooves 40, whereby the demand of avoiding the accumulation of the anisotropic conductive adhesive at multiple positions can be met.

In some implementations, as shown in FIG. 2, n grooves 40 are provided on at least one side of the hollow 30, a spacing between two adjacent grooves 40 is d2, n is an integer and n≥2, and 50μm≤d2≤100μm. In this implementation, the spacing d2 between adjacent grooves 40 is set to meet a certain range. The spacing d2 cooperates with the width d1 of the grooves 40, so that a relatively large number of grooves 40 can be provided in a limited space, realizing the release of the accumulation of the anisotropic conductive adhesive at multiple positions and preventing the accumulation of bubbles.

In some implementations, a plurality of grooves 40 are provided at equal intervals on at least one side of the hollow 30. Such an arrangement enables the force on the anisotropic conductive adhesive to be relatively uniform on at least one side of the hollow 30 during the bonding process, so that the anisotropic conductive adhesive can flow relatively uniformly along the grooves 40, enabling better release of the accumulation of the anisotropic conductive adhesive at multiple positions.

In other implementations, n grooves 40 are provided on at least one side of the hollow 30, n≥2, and the n grooves 40 may also be provided at unequal intervals.

In some implementations, as shown in FIG. 2, a length of the hollow 30 in the first direction a is greater than a length thereof in the second direction b. The first direction a and the second direction b are each parallel to a plane of the substrate 00, and the first direction a and the second direction b intersect each other. Herein, the groove 40 is provided on at least one side of the hollow 30 along the second direction b. In the top view, the shape of the hollow 30 is roughly a long strip, and its shape can be designed to adapt to the shape of the driver chip. The length of the hollow 30 on both sides in the second direction b is relatively long, and the length of the boundary of the organic layer 20 extending along the first direction a is also relatively long. During the bonding process, the organic layer 20 will come into contact with more anisotropic conductive adhesive on both sides in the second direction b. Providing the groove 40 on at least one side of the hollow 30 along the second direction b can utilize the groove 40 as a release path for bubbles in the anisotropic conductive adhesive, avoiding bubble generation due to the accumulation of the anisotropic conductive adhesive at this position, thereby being capable of preventing film layer peeling between the anisotropic conductive adhesive and the metal caused by the invasion of moisture and sweat.

FIG. 2 schematically shows that the groove 40 is provided on both sides of the hollow 30 along the second direction b. In some implementations, the groove 40 is provided only on one side of the hollow 30 along the second direction b, which is not schematically shown in the drawings here.

In some implementations, FIG. 7 is another schematic diagram of a display panel according to an embodiment of the present application. FIG. 7 illustrates a partial position of the display panel. As shown in FIG. 7, the hollow 30 has a first side C1 and a second side C2 opposite to each other in the second direction b. Along the second direction b, a distance from the first side C1 to the display area AA is smaller than a distance from the second side C2 to the display area AA. Herein, a length of the groove 40 in communication with the first side C1 in its extending direction is d11, and a length of the groove 40 in communication with the second side C2 in its extending direction is d12, where d11>d12. In the display panel, the bent state of the bending area BA2 can be utilized to enable the bonding area BA1 to be placed on the side away from the light-emitting surface of the display panel. That is, the bonding area BA1 and part of the structure located in the bonding area BA1 and away from the display area AA are placed on the side away from the light-emitting surface of the display panel. However, the part of the structure located in the bonding area BA1 and away from the display area AA generally needs to be bonded and connected to a flexible circuit board, and thus compared with the second side C2, the first side C1 of the hollow 30 in the second direction b has more free space. In the embodiment of the present application, the groove 40 with a relatively large extending length is provided in the free space between the first side C1 and the bending area BA2, which can make the flow of the anisotropic conductive adhesive at the position of the first side C1 smoother during the bonding and pressing process, and more effectively prevent the anisotropic conductive adhesive from accumulating and generating bubbles.

In some implementations, as shown in FIG. 2, the groove 40 is provided on at least one side of the hollow 30 along the first direction a. In this implementation, the groove 40 is provided on at least one side of the hollow 30 along the first direction a and at least one side of the hollow 30 along the second direction b, which can enhance the ability of the anisotropic conductive adhesive to flow in multiple directions during the bonding and pressing process, avoiding the anisotropic conductive adhesive generating bubble accumulation at the boundary position of the organic layer 20.

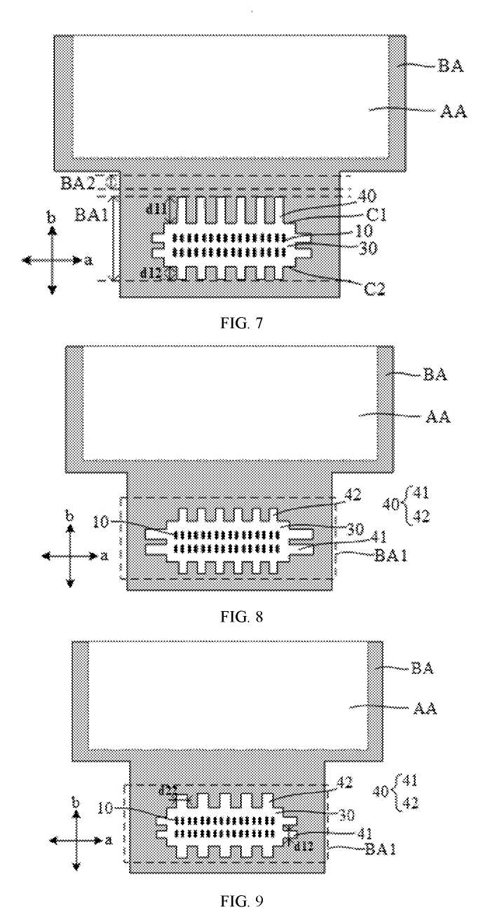

In some implementations, FIG. 8 is another schematic diagram of a display panel according to an embodiment of the present application. As shown in FIG. 8, the groove 40 includes a first groove 41 and a second groove 42. The first groove 41 is located on one side of the hollow 30 in the first direction a, and the second groove 42 is located on one side of the hollow 30 in the second direction b; a length of the first groove 41 in its extending direction is greater than a length of the second groove 42 in its extending direction. As can be seen from FIG. 8, the extending length of the first groove 41 in the first direction a is greater than the extending length of the second groove 42 in the second direction b. Considering that the position where the hollow 30 is located is used for bonding the driver chip, after the shape of the hollow 30 is designed according to the size of the driver chip, relatively large spaces are still reserved on both sides of the hollow 30 along the first direction a. Setting the first groove 41 to have a relatively large length in its extending direction can realize rational utilization of the space in the non-display area, enabling the flow of the anisotropic conductive adhesive in the first direction a to be smoother during the bonding process, whereby the flow volume of the anisotropic conductive adhesive in the second direction b can also be reduced to a certain extent, so that bubbles will not be generated due to the accumulation of the anisotropic conductive adhesive at the positions of the boundary of the organic layer 20 extending along the first direction a and the boundary extending along the second direction b.

In some implementations, FIG. 9 is another schematic diagram of a display panel according to an embodiment of the present application. As shown in FIG. 9, the groove 40 includes a first groove 41 and a second groove 42. The first groove 41 is located on one side of the hollow 30 in the first direction a, and the second groove 42 is located on one side of the hollow 30 in the second direction b; and the first groove 41 extends along the first direction a, and the second groove 42 extends along the second direction b. A width of the first groove 41 in a direction perpendicular to its extending direction is d12, and a width of the second groove 42 in a direction perpendicular to its extending direction is d22, where d12<d22. In the embodiment of the present application, the length of the hollow 30 in the first direction a is greater than its length in the second direction b, and thus the amount of the anisotropic conductive adhesive that comes into contact with the boundary of the organic layer 20 extending along the first direction a will be relatively larger. Thus, on one side of the hollow 30 along the second direction b, the groove 40 can be set to have a relatively larger width or a relatively larger number, so as to avoid bubble generation due to the accumulation of the anisotropic conductive adhesive at different positions of the boundary of the organic layer 20 extending along the first direction a.

It can be understood that a top view direction of the display panel when viewed from the top is parallel to a projection direction of an orthographic projection of the groove 40 onto the substrate. In the top views schematically shown in the above-mentioned embodiments, the shape of the groove 40 is roughly a rectangle, that is, the shape of the orthographic projection of the groove 40 onto the substrate 00 is a rectangle. In other implementations, the shape of the orthographic projection of the groove 40 onto the substrate 00 may also be at least one of a triangle, a trapezoid, a circle, and an ellipse.

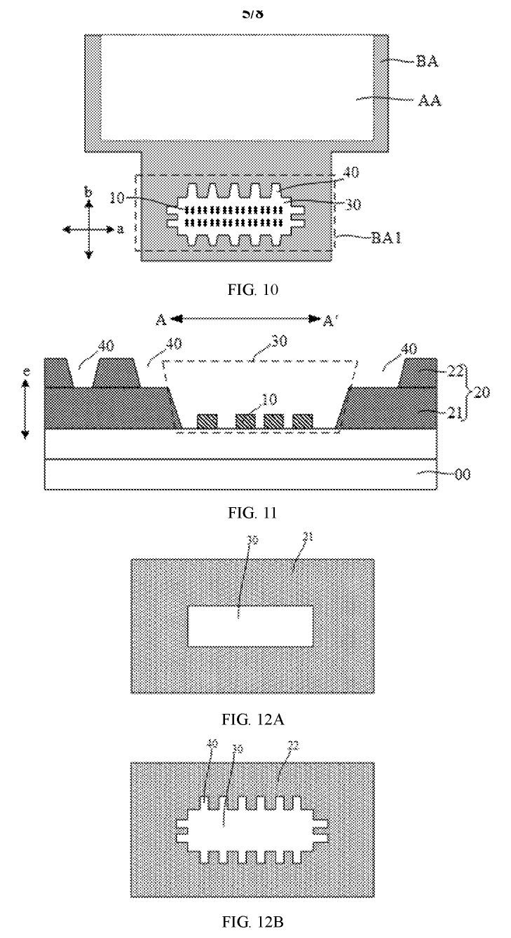

FIG. 10 is another partial schematic diagram of a display panel according to an embodiment of the present application. As can be seen from the top view of FIG. 10, the shape of the orthographic projections of part of the grooves 40 onto the substrate 00 is a trapezoid, and the shape of the orthographic projections of part of the grooves 40 onto the substrate 00 is a rectangle.

In some implementations, FIG. 11 is another cross-sectional schematic diagram taken at the position of section line A-A’ in FIG. 2. As shown in FIG. 11, the organic layer 20 includes a first organic layer 21 and a second organic layer 22, and the second organic layer 22 is located on one side of the first organic layer 21 away from the substrate 00; and along a direction e perpendicular to a plane of the substrate 00, the hollow 30 of the first organic layer 21 and the hollow 30 of the second organic layer 22 at least partially overlap. Herein, the first organic layer 21 does not have the groove, and the second organic layer 22 has the groove 40.

FIGS. 12A and 12B are top view schematic diagrams of the first organic layer and the second organic layer in the bonding area in FIG. 11. FIGS. 12A and 12B only illustrate the first organic layer 21 and the second organic layer 22 at a partial position of the bonding area BA1. FIG. 12A is a partial top view of the first organic layer 21, and FIG. 12B is a partial top view of the second organic layer 22. It can be seen that both the first organic layer 21 and the second organic layer 22 have the hollow 30, and the first organic layer 21 does not have the groove, while the second organic layer 22 has the groove 40.

In this implementation, the organic layer 20 located in the bonding area BA1 includes the first organic layer 21 and the second organic layer 22, both the first organic layer 21 and the second organic layer 22 have the hollow 30, and the groove 40 is provided on one of the first organic layer 21 and the second organic layer 22 to be in communication with the hollow 30. Such an arrangement can utilize the groove 40 as a bubble release path, preventing the anisotropic conductive adhesive from generating bubble accumulation at the boundary position of the organic layer 20. Moreover, the organic layer 20 without the groove 40 can cover some circuits arranged below the groove 40 at the overlapping position with the groove 40 in the direction e, avoiding the exposure of metal lines to the outside leading to corrosion risk.

In other implementations, along the direction e perpendicular to the plane of the substrate 00, the hollow 30 of the first organic layer 21 and the hollow 30 of the second organic layer 22 at least partially overlap, the first organic layer 21 has the groove 40, and the second organic layer 22 does not have the groove, which is not schematically shown in the drawings here.

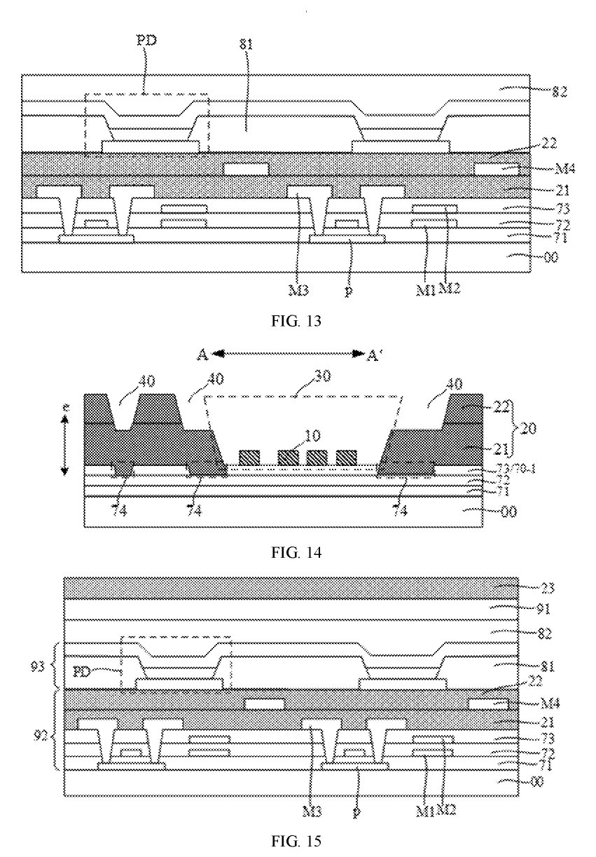

In some implementations, FIG. 13 is a schematic diagram of a film layer structure of a display panel according to an embodiment of the present application. As shown in FIG. 13, the display panel includes a semiconductor layer p, a first metal layer M1, a second metal layer M2, a third metal layer M3, and a fourth metal layer M4 located on the one side of the substrate 00, and the first metal layer M1, the second metal layer M2, the third metal layer M3, and the fourth metal layer M4 are sequentially arranged in a direction away from the substrate 00. Herein, active layers of transistors are located in the semiconductor layer p; gates of the transistors, first plates of storage capacitors, and some control signal lines are located in the first metal layer M1; second plates of the storage capacitors and some signal lines are located in the second metal layer M2; sources and drains of part of the transistors and some connecting lines are located in the third metal layer M3; and data lines and/or power lines are located in the fourth metal layer M4. Herein, at least part of the first organic layer 21 is located between the third metal layer M3 and the fourth metal layer M4, and at least part of the second organic layer 22 is located on one side of the fourth metal layer M4 away from the substrate 00. As shown in FIG. 13, the display panel further includes a light-emitting device PD, which is located on one side of the second organic layer 22 away from the substrate 00; a pixel definition layer 81 is used to space adjacent light-emitting devices PD; an encapsulation layer 82 is further provided on one side of the light-emitting device PD away from the substrate 00, and the encapsulation layer 82 is used to isolate water and oxygen to protect the light-emitting device PD.

In the embodiment of the present application, the groove 40 is provided on at least one of the first organic layer 21 and the second organic layer 22 located in the bonding area BA1, and the groove 40 is provided to be in communication with the hollow 30. During the bonding process between the display panel and the driver chip, the groove 40 can be utilized as a bubble release path, preventing the anisotropic conductive adhesive from generating bubble accumulation at the boundary position of the organic layer 20. This cuts off the invasion path of moisture and sweat, thereby being capable of preventing film layer peeling between the anisotropic conductive adhesive and the metal, and also improving product reliability.

As shown in FIG. 13, an inorganic layer 71 is provided between the semiconductor layer p and the first metal layer M1, an inorganic layer 72 is provided between the first metal layer M1 and the second metal layer M2, and an inorganic layer 73 is provided between the second metal layer M2 and the third metal layer M3. In some implementations, a trench is provided on at least one of the above-mentioned three inorganic layers.

FIG. 14 is another cross-sectional schematic diagram taken at the position of section line A-A’ in FIG. 2. As shown in FIG. 14, the display panel further includes a first inorganic layer 70-1 located on one side of the first organic layer 21 close to the substrate 00; the first inorganic layer 70-1 has a first trench 74 located in the bonding area; and along the direction e perpendicular to the plane of the substrate 00, the first trench 74 at least partially overlaps the groove 40. FIG. 14 takes the example where the first trench 74 is provided in the inorganic layer 73 between the second metal layer M2 and the third metal layer M3.

In the embodiment of the present application, the hollow 30 is provided in both the first organic layer 21 and the second organic layer 22 in the bonding area, and the groove 40 is provided in one of the first organic layer 21 and the second organic layer 22 to be in communication with the hollow 30. Meanwhile, the first trench 74 is provided in at least one first inorganic layer 70-1, and the first trench 74 at least partially overlaps the groove 40. By way of example, the groove 40 is formed in the second organic layer 22. Since the first inorganic layer 70-1 is located on the side of the first organic layer 21 close to the substrate 00, when the first organic layer 21 is formed on the first inorganic layer 70-1, the first organic layer 21 will fill the first trench 74 and form a recessed area of a certain size on the surface of the organic layer, then the groove 40 formed in the second organic layer 22 overlaps the first trench 74, which can increase the depth of the groove 40. Thus, under the condition that the length and width of the groove 40 are fixed, the depth of the groove 40 is increased, which also increases the flow space of the anisotropic conductive adhesive during the bonding process, and improves the ability to release bubbles in the anisotropic conductive adhesive.

In other implementations, FIG. 15 is another schematic diagram of a film layer structure of a display panel according to an embodiment of the present application. As shown in FIG. 15, the display panel includes a semiconductor layer p, a first metal layer M1, a second metal layer M2, a third metal layer M3, and a fourth metal layer M4 located on one side of the substrate 00, and the first metal layer M1, the second metal layer M2, the third metal layer M3, and the fourth metal layer M4 are sequentially arranged in a direction away from the substrate 00. The semiconductor layer p and these four metal layers are all located in a driving layer 92, and pixel circuits, shift driving circuits and some signal lines are arranged in the driving layer 92. A device layer 93 is provided on one side of the driving layer 92 away from the substrate 00, and the device layer 93 includes a pixel definition layer 81 and a plurality of light-emitting devices PD. An encapsulation layer 82 is provided on one side of the device layer 93 away from the substrate 00. A touch layer 91 is provided on one side of the encapsulation layer 82 away from the substrate 00, touch electrodes (not shown in FIG. 15) are arranged in the touch layer 91, and the touch layer 91 can realize the touch function of the display panel. Optionally, a cover plate (not shown in FIG. 15) is further provided on one side of the touch layer 91 away from the substrate 00.

The organic layer 20 in the display panel includes a first organic layer 21, a second organic layer 22, and a third organic layer 23, and the first organic layer 21, the second organic layer 22, and the third organic layer 23 are sequentially arranged in a direction away from the substrate 00. Herein, at least part of the first organic layer 21 is located between the third metal layer M3 and the fourth metal layer M4, and at least part of the second organic layer 22 is located on one side of the fourth metal layer M4 away from the substrate 00, that is, at least part of the first organic layer 21 and at least part of the second organic layer 22 are located in the driving layer. In addition, at least part of the third organic layer 23 is located on the side of the touch layer 91 away from the substrate 00. The third organic layer 23 can be, for example, optically clear adhesive, which plays a bonding role between the touch layer 91 and the cover plate.

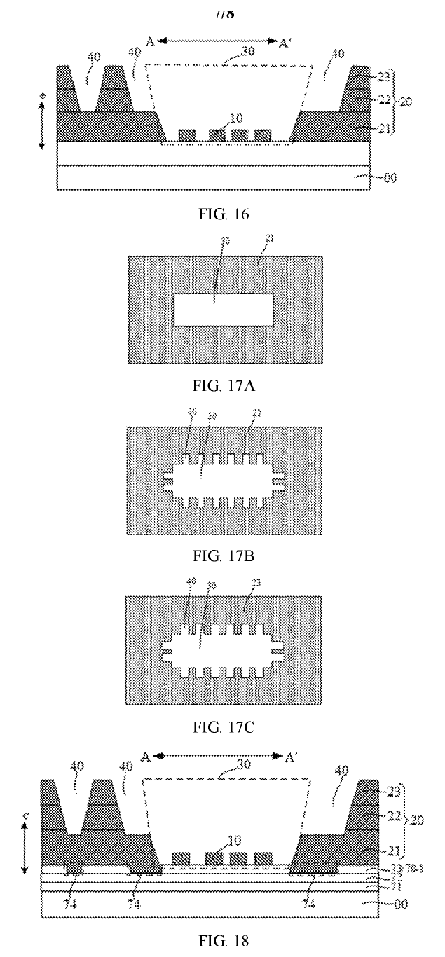

In some implementations, FIG. 16 is another cross-sectional schematic diagram taken at the position of section line A-A’ in FIG. 2. FIGS. 17A, 17B, and 17C are partial top view schematic diagrams of the three organic layers in the bonding area in FIG. 16. As shown in FIG. 16, along the direction e perpendicular to the plane of the substrate 00, the hollow 30 of the first organic layer 21, the hollow 30 of the second organic layer 22, and the hollow 30 of the third organic layer 23 at least partially overlap. FIG. 17A is a top view of the first organic layer 21, FIG. 17B is a top view of the second organic layer 22, and 17C is a top view of the third organic layer 23. It can be seen from FIGS. 17A-17C that the first organic layer 21 does not have the groove, while both the second organic layer 22 and the third organic layer 23 have the groove 40. As can be seen in conjunction with FIG. 16, the groove 40 of the second organic layer 22 and the groove 40 of the third organic layer 23 overlap in the direction e perpendicular to the plane of the substrate 00. In this implementation, when there are three organic layers 20 in the bonding area, all three organic layers 20 are provided with the hollow 30 to expose the metal bumps 10; then the grooves 40 are formed on two of the three organic layers 20, such that the grooves 40 are in communication with the hollows 30, and the grooves 40 located in the two organic layers 20 overlap in the direction e, which can increase the depth of the grooves 40 under the condition that the length and width of the grooves 40 are fixed, thereby increasing the flow space of the anisotropic conductive adhesive during the bonding process and improving the ability to release bubbles in the anisotropic conductive adhesive. In addition, there is at least one organic layer without the groove among the three organic layers 20, and this organic layer can cover some circuits arranged below the grooves 40, avoiding the exposure of metal lines to the outside leading to corrosion risk.

FIG. 16 illustrates the case where both the second organic layer 22 and the third organic layer 23 are provided with the groove 40. In other implementations, both the first organic layer 21 and the second organic layer 22 are provided with the groove 40 in communication with the hollow 30, or both the first organic layer 21 and the third organic layer 23 are provided with the groove 40 in communication with the hollow 30, which are not schematically shown in the drawings here.

In other implementations, one of the first organic layer 21, the second organic layer 22, and the third organic layer 23 has the groove 40, which is not schematically shown in the drawings here. At least one organic layer 20 among the three organic layers 20 is provided with the groove in communication with the hollow 30, and at least one organic layer 20 is provided with only the hollow 30 without the groove. This not only enables the groove 40 to be utilized as a bubble release path, preventing the anisotropic conductive adhesive from generating bubble accumulation at the boundary position of the organic layer 20, but also enables the organic layer 20 without the groove to cover metal wirings located below the groove 40, preventing corrosion caused by exposed wirings.

In some implementations, as shown in FIG. 15, an inorganic layer 71 is provided between the semiconductor layer p and the first metal layer M1, an inorganic layer 72 is provided between the first metal layer M1 and the second metal layer M2, and an inorganic layer 73 is provided between the second metal layer M2 and the third metal layer M3. In some implementations, a trench located in the bonding area BA1 is provided in at least one of the above-mentioned three inorganic layers.

FIG. 18 is another cross-sectional schematic diagram taken at the position of section line A-A’ in FIG. 2. As shown in FIG. 18, the display panel further includes a first inorganic layer 70-1 located on one side of the first organic layer 21 close to the substrate 00; and at least one first inorganic layer has a first trench 74 located in the bonding area. FIG. 18 takes the example where the inorganic layer 73 is a first inorganic layer 70-1 provided with the first trench 74. Along the direction e perpendicular to the plane of the substrate 00, the first trench 74 at least partially overlaps the groove 40. In this implementation, the first inorganic layer 70-1 is located on the side of the first organic layer 21 close to the substrate 00; although in the display panel, the thickness of the organic layer is generally greater than the thickness of the inorganic layer, when the first trench 74 is formed in the first inorganic layer 70-1, the organic layer formed on top thereof cannot completely fill the first trench 74, but will form a recessed area of a certain size on the surface of the organic layer. Thus, when the second organic layer 22 and the third organic layer 23 are formed on top of the first organic layer 21, arranging the grooves 40 of the second organic layer 22 and the third organic layer 23 to overlap the first trench 74 can increase the depth of the grooves 40, so that under the condition that the length and width of the grooves 40 are fixed, the depth of the grooves 40 is increased, which also increases the flow space of the anisotropic conductive adhesive during the bonding process and improves the ability to release bubbles in the anisotropic conductive adhesive.

FIG. 18 only illustrates the case where the first trench 74 is provided in the inorganic layer 73. In other implementations, the first trench 74 can also be provided in the inorganic layer 72 and/or the inorganic layer 71, which are not schematically shown in the drawings here.

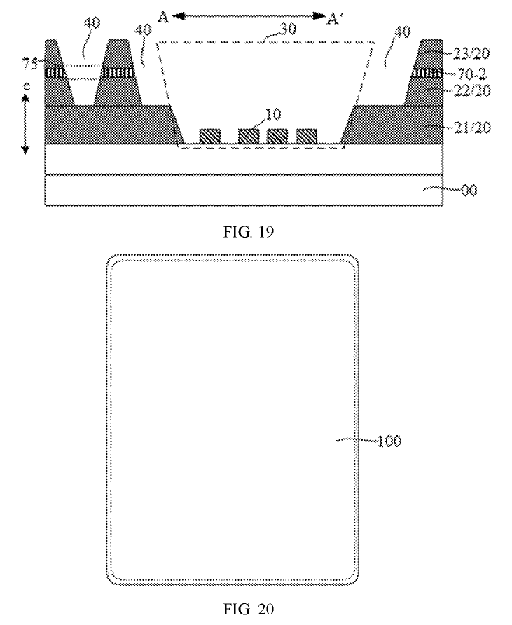

In other implementations, FIG. 19 is another cross-sectional schematic diagram taken at the position of section line A-A’ in FIG. 2. As shown in FIG. 19, the display panel further includes a second inorganic layer 70-2 located between the second organic layer 22 and the third organic layer 23; the second inorganic layer 70-2 has a second trench 75 located in the bonding area BA1; and along the direction e perpendicular to the plane of the substrate 00, the second trench 75 at least partially overlaps the groove 40. Herein, the second inorganic layer 70-2 can be an inorganic layer in the touch layer 91, such as the inorganic layer between two metal layers in the touch layer 91. In this implementation, the second trench 75 is formed in the second inorganic layer 70-2 between the second organic layer 22 and the third organic layer 23, and the second trench 75 overlaps the groove 40, and thus the second trench 75 is in communication with the hollow 30. By arranging the second trench 75 to overlap the groove 40, the flow space of the anisotropic conductive adhesive during the bonding process can be increased, and the ability to release bubbles in the anisotropic conductive adhesive can be improved.

Based on the same inventive concept, an embodiment of the present application further provides a display apparatus. FIG. 20 is a schematic diagram of a display apparatus according to an embodiment of the present application. As shown in FIG. 20, the display apparatus includes the display panel 100 according to any of the embodiments of the present application. The structure of the display panel 100 has been described in the above-mentioned embodiments, and will not be repeated here. For example, the display apparatus according to the embodiment of the present application may be an electronic device with a display function, such as a mobile phone, a tablet, a computer, a television, a smart wearable product, etc.

The above are merely preferred embodiments of the present application, and are not intended to limit the present application. Any modification, equivalent replacement, improvement, etc. made within the spirit and principle of the present application shall be included in the protection scope of the present application.

Finally, it should be noted that the above-mentioned embodiments are only used to describe the technical solutions of the present application, and are not intended to limit the present application; although the present application has been described in detail with reference to the foregoing embodiments, those of skill in the art should understand that they can still modify the technical solutions recited in the foregoing embodiments, or equivalently replace some or all of the technical features therein; and these modifications or replacements do not make the essence of the corresponding technical solutions depart from the scope of the technical solutions of the embodiments of the present application.

What is claimed is:

1. A display panel, comprising a display area and a non-display area, the non-display area comprising a bonding area;
wherein the display panel comprises a substrate, and metal bumps and organic layers that are located on one side of the substrate, the organic layers having a hollow located in the bonding area, and the metal bumps being located in the hollow; and
wherein at least one of the organic layers has a groove, the groove being in communication with the hollow and extending in a direction away from the hollow.

2. The display panel according to claim 1, wherein
a length of the hollow in a first direction is greater than a length of the hollow in a second direction, the first direction and the second direction are each parallel to a plane of the substrate, and the first direction and the second direction intersect each other; and
the groove is provided on at least one side of the hollow along the second direction.

3. The display panel according to claim 2, wherein
the hollow has a first side and a second side opposite to each other in the second direction, and along the second direction, a distance from the first side to the display area is smaller than a distance from the second side to the display area; and
wherein a length of the groove in communication with the first side in its extending direction is d11, and a length of the groove in communication with the second side in its extending direction is d12, and d11>d12.

4. The display panel according to claim 2, wherein
the groove is provided on at least one side of the hollow along the first direction.

5. The display panel according to claim 4, wherein
the groove comprises a first groove and a second groove, the first groove is located on one side of the hollow in the first direction, and the second groove is located on one side of the hollow in the second direction; and
wherein a length of the first groove in its extending direction is greater than a length of the second groove in its extending direction, and/or a width of the first groove in a direction perpendicular to its extending direction is smaller than a width of the second groove in a direction perpendicular to its extending direction.

6. The display panel according to claim 1, wherein
a length of the groove in its extending direction is L, and L≥100μm.

7. The display panel according to claim 6, wherein
L≤150μm.

8. The display panel according to claim 1, wherein
along a direction perpendicular to an extending direction of the groove, a width of the groove is d1, and 50μm≤d1≤100μm.

9. The display panel according to claim 1, wherein
n grooves are provided on at least one side of the hollow, a spacing between two adjacent grooves is d2, n is an integer and n≥2, and 50μm≤d2≤100μm.

10. The display panel according to claim 1, wherein
a plurality of grooves are arranged at equal intervals on at least one side of the hollow.

11. The display panel according to claim 1, wherein
a shape of an orthographic projection of the groove onto the substrate is at least one selected from a group consisting of a rectangle, a triangle, a trapezoid, a circle, and an ellipse.

12. The display panel according to claim 1, wherein
the organic layers comprise a first organic layer and a second organic layer, and the second organic layer is located on one side of the first organic layer away from the substrate; and
along a direction perpendicular to a plane of the substrate, the hollow of the first organic layer and the hollow of the second organic layer at least partially overlap;
wherein one of the first organic layer and the second organic layer has the groove.

13. The display panel according to claim 12, wherein
the display panel comprises a first metal layer, a second metal layer, a third metal layer, and a fourth metal layer located on the one side of the substrate, and the first metal layer, the second metal layer, the third metal layer, and the fourth metal layer are sequentially arranged in a direction away from the substrate; and
at least part of the first organic layer is located between the third metal layer and the fourth metal layer, and at least part of the second organic layer is located on one side of the fourth metal layer away from the substrate.

14. The display panel according to claim 13, wherein
the display panel further comprises a first inorganic layer located on one side of the first organic layer close to the substrate; and
the first inorganic layer has a first trench located in the bonding area; and along the direction perpendicular to the plane of the substrate, the first trench at least partially overlaps the groove.

15. The display panel according to claim 1, wherein
the organic layers comprise a first organic layer, a second organic layer, and a third organic layer, and the first organic layer, the second organic layer, and the third organic layer are sequentially arranged in a direction away from the substrate; and
along a direction perpendicular to a plane of the substrate, the hollow of the first organic layer, the hollow of the second organic layer, and the hollow of the third organic layer at least partially overlap;
wherein one of the first organic layer, the second organic layer, and the third organic layer has the groove; or two of the first organic layer, the second organic layer, and the third organic layer have the groove, and the grooves of these two organic layers overlap in the direction perpendicular to the plane of the substrate.

16. The display panel according to claim 15, wherein
the display panel further comprises a first inorganic layer located on one side of the first organic layer close to the substrate; and
at least one first inorganic layer has a first trench located in the bonding area; and along the direction perpendicular to the plane of the substrate, the first trench at least partially overlaps the groove.

17. The display panel according to claim 15, wherein
the display panel further comprises a second inorganic layer located between the second organic layer and the third organic layer;
the second inorganic layer has a second trench located in the bonding area; and
along the direction perpendicular to the plane of the substrate, the second trench at least partially overlaps the groove.

18. The display panel according to claim 15, wherein
the display panel comprises a driving layer, a device layer, and a touch layer, the device layer is located on one side of the driving layer away from the substrate, and the touch layer is located on one side of the device layer away from the substrate;
wherein at least part of the first organic layer and at least part of the second organic layer are located in the driving layer, and at least part of the third organic layer is located on one side of the touch layer away from the substrate.

19. The display panel according to claim 1, wherein
the display panel comprises a driver chip, the driver chip comprises a plurality of pins; and in the hollow, the pins and the metal bumps are connected through an anisotropic conductive adhesive; and
the anisotropic conductive adhesive fills at least part of the groove.

20. A display apparatus, comprising a display panel, wherein the display panel comprises a display area and a non-display area, the non-display area comprising a bonding area;
wherein the display panel comprises a substrate, and metal bumps and organic layers that are located on one side of the substrate, the organic layers having a hollow located in the bonding area, and the metal bumps being located in the hollow; and
wherein at least one of the organic layers has a groove, the groove being in communication with the hollow and extending in a direction away from the hollow.
